(19) United States
(12) Patent Application Publication
(10) Pub. No.: US 2026/0057930 A1
(43) Pub. Date: Feb. 26, 2026

(54) SEMICONDUCTOR DEVICE

(71) Applicant: SK hynix Inc., Gyeonggi-do (KR)

(72) Inventor: Sun Jong YOO, Gyeonggi-do (KR)

(21) Appl. No.: 19/310,752

(22) Filed: Aug. 26, 2025

(30) Foreign Application Priority Data
Aug. 26, 2024 (KR) 10-2024-0114383

(51) Int. Cl. G11C 11/408; H10B 12/00

(52) U.S. Cl. CPC G11C 11/4085; H10B 12/315

(57) ABSTRACT

Disclosed is a semiconductor device which includes a substrate, a vertical pattern including a semiconductor region and extending in a direction perpendicular to one surface of the substrate, and a word line disposed in contact with a side surface of the vertical pattern and extending in a direction parallel to the one surface of the substrate. The word line may include a first sub-word line disposed adjacent to the substrate, a second sub-word line located above the first sub-word line, and a third sub-word line located above the second sub-word line.

### CROSS-REFERENCE TO RELATED APPLICATIONS

This application claims the benefit of priority to Korean Patent Application No. 10-2024-0114383, filed on Aug. 26, 2024, the entire contents of which are incorporated herein by reference.

### TECHNICAL FIELD

The present disclosure relates to a semiconductor device, and more particularly, to a semiconductor device including a memory cell.

### BACKGROUND

As the miniaturization and improvement of integration of semiconductor devices emerges as a point of focus, researchers and manufacturers have focused on forming memory cells, which the semiconductor device includes, to have a three-dimensional pattern. The memory cells having the three-dimensional pattern may include components for improving operating characteristics of the semiconductor devices.

### SUMMARY

The present disclosure has been made to solve the above-mentioned problems occurring in the prior art while maintaining intact advantages achieved by the prior art.

An aspect of the present disclosure provides an integrated circuit device having an excellent electrical characteristic by preventing a leakage current from being generated.

The technical problems to be solved by the present disclosure are not limited to the aforementioned problems, and any other technical problems not mentioned herein will be clearly understood from the following description by those skilled in the art to which the present disclosure pertains.

According to an embodiment of the present disclosure, a semiconductor device may include a substrate, a vertical pattern including a semiconductor region and extends in a direction perpendicular to one surface of the substrate, and a word line disposed in contact with a side surface of the vertical pattern and extending in a direction parallel to the one surface of the substrate. The word line may include a first sub-word line disposed adjacent to the substrate, a second sub-word line located above the first sub-word line, and a third sub-word line located above the second sub-word line.

According to an embodiment, the semiconductor device may further include a word line driving circuit connected to the word line, and the word line driving circuit may include a first keeping transistor. The first keeping transistor may include a source connected to the second sub-word line, a drain connected to the first sub-word line and the third sub-word line, and a gate configured to receive a first voltage.

According to an embodiment, the word line driving circuit may further include a second keeping transistor, and the second keeping transistor may include a source configured to receive the first voltage, a drain connected to the second sub-word line, and a gate configured to receive an inverted word line driving signal.

According to an embodiment, the word line driving circuit may further include a first transistor, and the first transistor may include a source configured to receive a first word line driving signal, a drain connected to the second sub-word line, and a gate configured to receive a word line enable signal.

According to an embodiment, the word line driving circuit further include a second transistor, and the second transistor may include a source configured to receive the first voltage, a drain connected to the second sub-word line, and a gate configured to receive a word line enable signal.

According to an embodiment, the word line driving circuit is configured to provide the first voltage to the second sub-word line and provide a second voltage to the first sub-word line and the third sub-word line, during a time period in which the word line is set to a standby state.

According to an embodiment, a width of a cross-sectional area of the first sub-word line may be less than a width of a cross-sectional area of the second sub-word line, and a width of a cross-sectional area of the third sub-word line may be less than the width of the cross-sectional area of the second sub-word line.

According to an embodiment, a width of a cross-sectional area of the first sub-word line may be the same as a width of a cross-sectional area of the third sub-word line.

According to an embodiment, the semiconductor device may further include a bit line, extending in the direction parallel to the one surface of the substrate, disposed in contact with the semiconductor region.

According to an embodiment, the bit line may extend in a direction perpendicular to the word line.

According to another embodiment of the present disclosure, a semiconductor device may include a bit line that extends in a first direction, a vertical pattern that extends in a third direction perpendicular to the first direction, one side of the vertical pattern being in contact with the bit line, a storage element disposed in contact with an opposite side of the vertical pattern, a first sub-word line disposed in contact with a side surface of the vertical pattern and extending in a second direction perpendicular to the third direction, a second sub-word line disposed in contact with the side surface of the vertical pattern and is spaced apart from the first sub-word line in the third direction, a third sub-word line disposed in contact with the side surface of the vertical pattern and is spaced apart from the second sub-word line in the third direction, and a first keeping transistor that is connected to the first sub-word line, the second sub-word line, and the third sub-word line. The first keeping transistor may include a drain connected to the first sub-word line and the third sub-word line, a source connected to the second sub-word line, and a gate configured to receive a first voltage.

According to another embodiment, the first keeping transistor may include a PMOS transistor.

According to another embodiment, the semiconductor device may further include a second keeping transistor, and the second keeping transistor may include a source configured to receive the first voltage, a drain connected to the second sub-word line, and a gate configured to receive an inverted word line driving signal.

According to another embodiment, the second keeping transistor may include an NMOS transistor.

According to another embodiment, the semiconductor device may further include a first transistor, and the first transistor may include a source configured to receive a word line driving signal, a drain connected to the second sub-word line, and a gate configured to receive a word line enable signal.

According to another embodiment, the first transistor may include a PMOS transistor.

According to another embodiment, the semiconductor device may further include a second transistor, and the second transistor may include a source configured to receive the first voltage, a drain connected to the second sub-word line, and a gate configured to receive a word line enable signal.

According to another embodiment, the second transistor may include an NMOS transistor.

According to another embodiment, the first voltage may be provided to the second sub-word line during a time period in which the first sub-word line, the second sub-word line, and the third sub-word line are set to a standby state, and a second voltage may be provided to the first sub-word line and the third sub-word line.

According to another embodiment, the second voltage may be higher than the first voltage.

### BRIEF DESCRIPTION OF THE DRAWINGS

The above and other objects, features and advantages of the present disclosure will be more apparent from the following detailed description taken in conjunction with the accompanying drawings:

FIG. 1 is a diagram illustrating an example of a connection configuration of a memory cell array of a semiconductor device according to an embodiment of the present disclosure;

FIG. 2 is a circuit diagram describing a word line driving circuit according to an embodiment of the present disclosure;

FIG. 3 is a timing diagram describing driving of a word line driving circuit according to an embodiment of the present disclosure;

FIG. 4 is a perspective view of a memory cell array according to an embodiment of the present disclosure; and

FIG. 5 is a cross-sectional view of a memory cell array taken along line A-A′ of FIG. 4 according to an embodiment of the present disclosure.

### DETAILED DESCRIPTION

Hereinafter, various embodiments of the present disclosure are described with reference to accompanying drawings. Advantages and features of the present disclosure and methods for implementing them will become apparent with reference to embodiments to be described below in detail together with the accompanying drawings. However, this is not intended to limit the present disclosure to specific embodiments.

The present disclosure may be implemented in various different forms without being limited to an embodiment and should be understood as including various modifications, equivalents, and/or alternatives of embodiments of the present disclosure.

Also, in adding reference numerals to components of each drawing, it should be noted that like components are designated by like numerals even though illustrated on other drawings.

In describing an embodiment of the present disclosure, if it is determined that a detailed description of a related known configuration or function hinders understanding of the embodiment of the present disclosure, the detailed description of the related known configuration or function is omitted.

In the specification, the singular forms include plural forms unless otherwise mentioned. The terms “comprises” and/or “comprising”, which are used in the specification, specify the presence of components, steps, operations, and/or elements, but do not preclude the presence or addition of one or more other components, steps, operations, and/or elements.

Below, a semiconductor device and a method of manufacturing the semiconductor device, according to embodiments of the present disclosure, will be described with reference to the accompanying drawings.

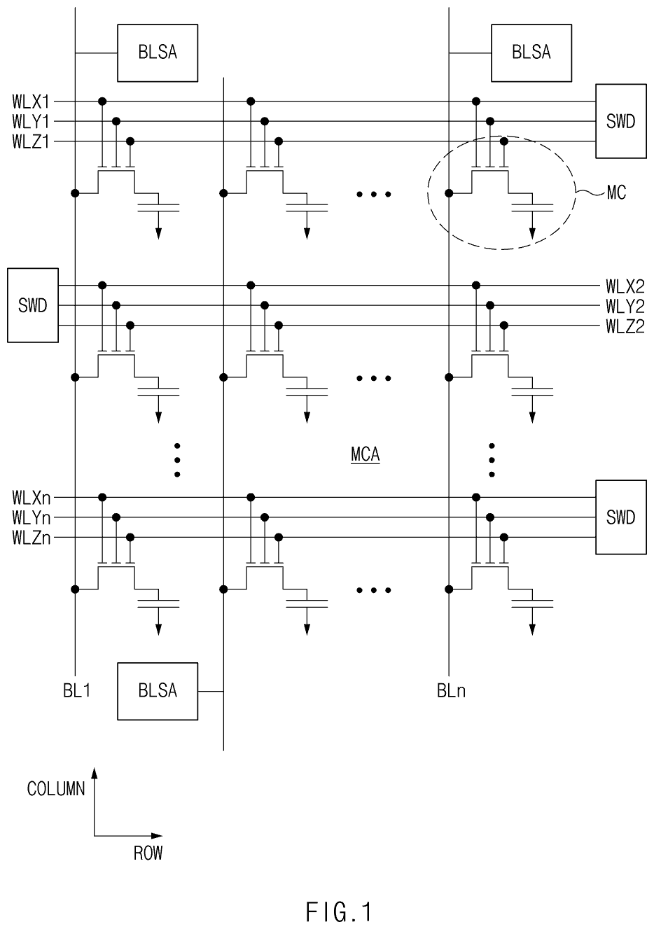

FIG. 1 is a diagram illustrating an example of a connection configuration of a memory cell array according to an embodiment of the present disclosure.

Referring to FIG. 1, a memory cell array (MCA) of a semiconductor device may include a plurality of memory cells MC.

The memory cell array may include an area in which the plurality of memory cells MC are arranged and a peripheral circuit area (not shown) in which a plurality of circuits connected to the memory cells MC are disposed.

Each memory cell MC may include a word line driving circuit SWD, a bit line sense amplifier BLSA, and a plurality of sub-word lines WLX1, WLY1, WLZ1, etc.

The word line driving circuit SWD may be connected to a first sub-word line (e.g., WLX1, WLX2, WLXn, etc.) a second sub-word line (e.g., WLY1, WLY2, WLYn, etc.), and a third sub-word line (e.g., WLZ1, WLZ2, WLZn, etc.).

The word line driving circuit SWD may control voltages to be provided to the first sub-word line (e.g., WLX1, WLX2, . . . , WLXn) the second sub-word line (e.g., WLY1, WLY2, . . . , WLYn), and the third sub-word line (e.g., WLZ1, WLZ2, . . . , WLZn) based on a word line enable signal and word line driving signals which are output from a row decoder.

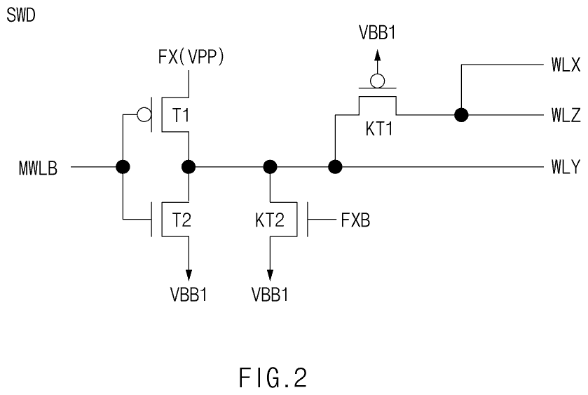

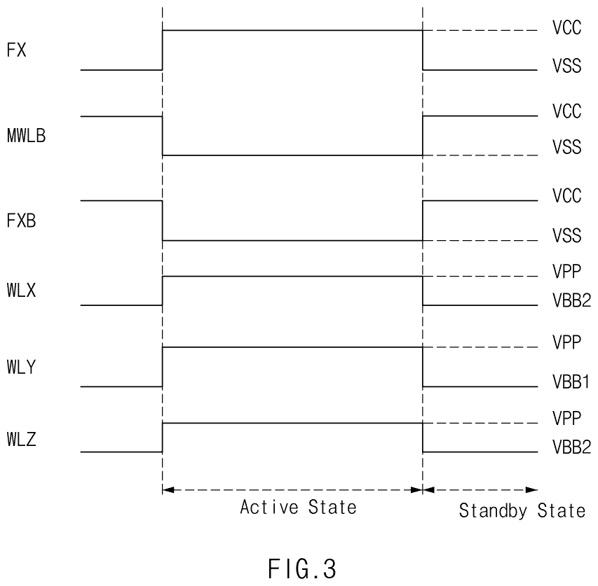

An operating method of the word line driving circuit SWD will be described in detail with reference to FIGS. 2 and 3.

The bit line sense amplifier BLSA may be connected to each of bit lines BL1, BL2, . . . , BLn, and each of the bit lines BL1, BL2, . . . , BLn may be connected in common to a plurality of memory cells MC disposed at each column of the memory cell array. The bit line sense amplifier BLSA may sense and output a voltage change of the connected bit line BL. As the bit line sense amplifier BLSA amplifies and outputs the voltage change, data stored in each of the memory cells MC may be amplified and output.

The plurality of memory cells MC disposed in the memory cell array may be connected to the first sub-word line (e.g., WLX1), the second sub-word line (e.g., WLY1), and the third sub-word line (e.g., WLZ1) disposed in parallel.

The first sub-word line (e.g., WLX1), the second sub-word line (e.g., WLY1), and the third sub-word line (e.g., WLZ1) may be gate electrodes which are in contact with a sidewall of a vertical pattern extending in a direction perpendicular to one surface of a substrate and are spaced apart from each other.

If the memory cell MC is selected, the same voltage may be applied to the first sub-word line (e.g., WLX1), the second sub-word line (e.g., WLY1), and the third sub-word line (e.g., WLZ1) connected to the memory cell MC. Thus, the first sub-word line (e.g., WLX1), the second sub-word line (e.g., WLY1), and the third sub-word line (e.g., WLZ1) may operate as one gate electrode.

If the memory cell MC is not selected, a voltage which is provided to the first sub-word line (e.g., WLX1) and the third sub-word line (e.g., WLZ1) may be different from a voltage which is applied to the second sub-word line (e.g., WLY1).

If the memory cell MC is not selected, a leakage current may be reduced or suppressed by adjusting the voltage which is provided to the first sub-word line (e.g., WLX1) and the third sub-word line (e.g., WLZ1).

The plurality of memory cells MC disposed in a row direction may be connected in common to the first sub-word line (e.g., WLX1), the second sub-word line (e.g., WLY1), and the third sub-word line (e.g., WLZ1).

The first sub-word line (e.g., WLX1), the second sub-word line (e.g., WLY1), and the third sub-word line (e.g., WLZ1) which are connected to the plurality of memory cells MC disposed in the row direction may be connected to one word line driving circuit SWD.

FIG. 2 is a circuit diagram describing the word line driving circuit SWD according to an embodiment of the present disclosure.

FIG. 3 is a timing diagram describing driving of a word line driving circuit according to an embodiment of the present disclosure.

An operating method of a word line driving circuit will be described with reference to FIGS. 2 and 3.

Referring to FIG. 2, the word line driving circuit SWD may include a first transistor T1, a second transistor T2, a first keeping transistor KT1, and a second keeping transistor KT2.

The first transistor T1 may be a P-type metal-oxide-semiconductor (PMOS) transistor. The first transistor T1 may include a source connected to a word line driving signal FX having a boosting voltage (VPP) level, a gate connected to a word line enable signal MWLB, and a drain connected to a second sub-word line WLY.

The second transistor T2 may be an N-type metal-oxide-semiconductor (NMOS) transistor. The second transistor T2 may include a source connected to a first voltage VBB1, a gate connected to the word line enable signal MWLB, and a drain connected to the second sub-word line WLY. The first voltage VBB1 may be a negative voltage.

The first keeping transistor KT1 may be a PMOS transistor. The first keeping transistor KT1 may include a source connected to the second sub-word line WLY, a gate connected to the first voltage VBB1, and a drain connected to a first sub-word line WLX and a third sub-word line WLZ.

The second keeping transistor KT2 may be an NMOS transistor. The second keeping transistor KT2 may include a source connected to the first voltage VBB1, a gate connected to an inverted word line driving signal FXB, and a drain connected to the second sub-word line WLY.

If the memory cell MC is selected, the word line driving circuit SWD may provide the boosting voltage VPP to the first sub-word line WLX, the second sub-word line WLY, and the third sub-word line WLZ thus connected; if the memory cell MC is not selected, the word line driving circuit SWD may provide the first voltage VBB1 to the second sub-word line WLY.

If the memory cell MC is not selected, the word line driving circuit SWD may provide a second voltage VBB2 to the first sub-word line WLX and the third sub-word line WLZ thus connected.

The second voltage VBB2 may be a voltage which is greater than the first voltage VBB1 and is less than the boosting voltage VPP. The absolute value of the second voltage VBB2 may be less than the absolute value of the first voltage VBB1. In other words, the second voltage VBB2 may be a positive voltage less than the boosting voltage VPP, and the first voltage VBB1 may be a negative voltage.

A voltage level difference between the second voltage VBB2 and the first voltage VBB1 may correspond, for example, to a threshold voltage level of the first keeping transistor KT1.

In an active state where the memory cell MC is selected, the word line driving circuit SWD may provide the boosting voltage VPP to the first to third sub-word lines WLX, WLY, and WLZ; in a standby state where the memory cell MC is not selected, the word line driving circuit SWD may provide the first voltage VBB1 to the second sub-word line WLY.

If the memory cell MC is in the standby state, the word line driving circuit SWD may provide the second voltage VBB2 to the first sub-word line WLX and the third sub-word line WLZ. As the second voltage VBB2 is set to be greater than the first voltage VBB1, a leakage current which is generated between the sub-word lines WLX, WLY, and WLZ included in a memory cell and a semiconductor region included in the vertical pattern in the standby state of the memory cell may be efficiently reduced.

As the word line driving circuit SWD includes the first keeping transistor KT1, a voltage which is different from a voltage provided to the second sub-word line WLY may be provided to the first sub-word line WLX and the third sub-word line WLZ without a separate voltage providing device.

Referring to FIG. 3, if the memory cell is in the active state, the word line driving signal FX may transition from a low level VSS to a high level VCC, and the word line enable signal MWLB may transition from the high level VCC to the low level VSS. Also, the inverted word line driving signal FXB may transition from the high level VCC to the low level VSS. A low level (VSS) voltage may be a ground voltage.

If the memory cell is in the active state, the word line driving signal FX may be maintained at the high level VCC, the word line enable signal MWLB may be maintained at the low level VSS, and the inverted word line driving signal FXB may be maintained at the low level VSS.

According to the above description, if the memory cell is in the active state, the first keeping transistor KT1 and the first transistor T1 may be set to an ON state. Also, the second transistor T2 and the second keeping transistor KT2 may be set to an OFF state.

If the memory cell is in the active state, the boosting voltage VPP may be provided to the first to third sub-word lines WLX, WLY, and WLZ. In the active state, the first to third sub-word lines WLX, WLY, and WLZ may operate as one word line.

If the memory cell is in the standby state, the word line driving signal FX may transition from the high level VCC to the low level VSS, and the word line enable signal MWLB may transition from the low level VSS to the high level VCC. Also, the inverted word line driving signal FXB may transition from the low level VSS to the high level VCC.

If the memory cell is in the standby state, the word line driving signal FX may be maintained at the low level VSS, the word line enable signal MWLB may be maintained at the high level VCC, and the inverted word line driving signal FXB may be maintained at the high level VCC.

Accordingly, if the memory cell is in the standby state, the first transistor T1 may be set to the OFF state, and the first keeping transistor KT1, the second transistor T2, and the second keeping transistor KT2 may be set to the ON state.

When the memory cell is in the standby state, the first voltage VBB1 may be provided to the second sub-word line WLY.

In contrast, as the first keeping transistor KT1 is provided in the word line driving circuit SWD, the second voltage VBB2 may be provided to the first sub-word line WLX and the third sub-word line WLZ.

If the memory cell is in the standby state, the first voltage VBB1 may be applied to the gate of the first keeping transistor KT1, and the first voltage VBB1 may be provided to the source of the first keeping transistor KT1.

If the same voltage, that is, the first voltage VBB1 is provided to the gate and the source, a voltage difference between the drain and the source of the first keeping transistor KT1 being in a saturate state may correspond to the threshold voltage of the first keeping transistor KT1.

In other words, as the first keeping transistor KT1 is provided in the word line driving circuit SWD and a voltage to be provided to the gate and the source of the first keeping transistor KT1 is adjusted, a voltage to be provided to the first sub-word line WLX and the third sub-word line WLZ and a voltage to be provided to the second sub-word line WLY may be controlled to be different from each other in the standby state.

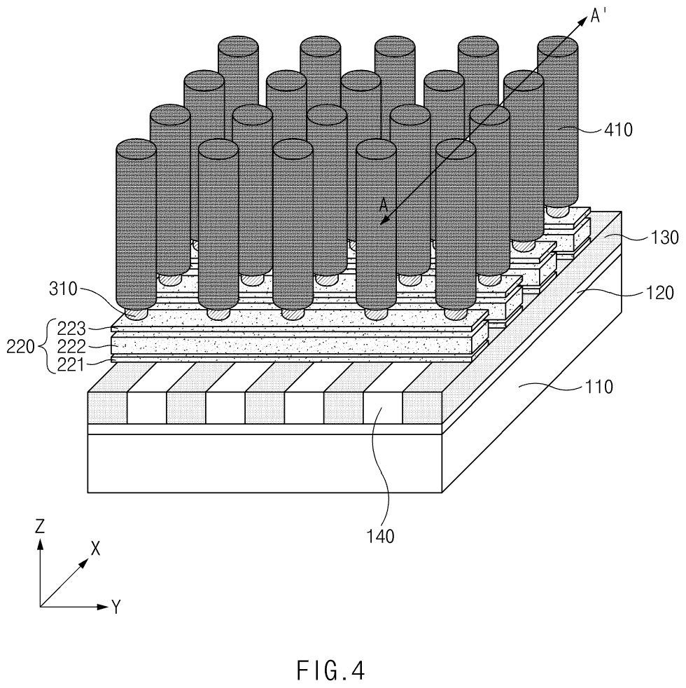

FIG. 4 is a perspective view of a memory cell array according to an embodiment of the present disclosure.

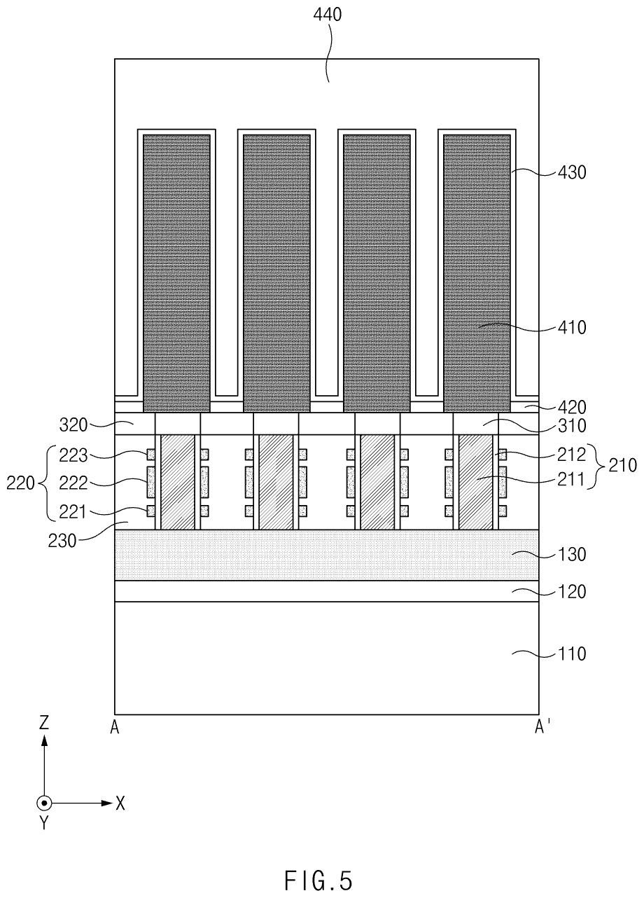

FIG. 5 is a cross-sectional view of a memory cell array taken along line A-A′ of FIG. 4.

A structure of a memory cell array will be described with reference to FIGS. 4 and 5.

The memory cell array may include a semiconductor substrate 110, a lower insulating layer 120, a bit line 130, a bit line insulating pattern 140, a vertical pattern 210, a word line 220, a word line insulating pattern 230, a capacitor contact 310, a contact insulating pattern 320, a capacitor lower electrode 410, a capacitor insulating pattern 420, a capacitor dielectric layer 430, and an upper electrode 440.

In FIG. 4, some components including the upper electrode 440 are omitted such that a placement shape of the bit line 130, the word line 220, and the capacitor lower electrode 410 is easily shown.

The memory cell array may include the semiconductor substrate 110. The semiconductor substrate 110 may include, for example, a material appropriate for semiconductor processing.

The semiconductor substrate 110 may be formed of a semiconductor material containing silicon, for example. The semiconductor substrate 110 may include silicon, single crystal silicon, polysilicon, amorphous silicon, silicon germanium, single crystal silicon germanium, polycrystalline silicon germanium, or carbon-doped silicon, a combination thereof, or a multi-layer thereof.

The semiconductor substrate 110 may include another semiconductor material such as germanium. The semiconductor substrate 110 may include a group III/V semiconductor substrate, for example, a compound semiconductor substrate such as GaAs.

The semiconductor substrate 110 may include a silicon on insulator (SOI) substrate.

The lower insulating layer 120 may be formed on the semiconductor substrate 110, and the bit lines 130 may be disposed on the lower insulating layer 120.

The lower insulating layer 120 may be a layer which includes an insulating material such as silicon nitride or silicon oxide.

The plurality of bit lines 130 formed on the lower insulating layer 120 may extend in a first direction (X direction) and may be spaced apart from each other in a second direction (Y direction). In addition to the plurality of bit lines 130, the plurality of bit line insulating patterns 140 may be disposed on the lower insulating layer 120.

A space between the bit lines 130 adjacent to each other may be filled by the bit line insulating pattern 140. A length of the bit line insulating pattern 140 in a third direction (Z direction) may be the same as a length of the bit lines 130 in the third direction.

The bit line 130 may be referred to as a “laterally-oriented bit line” or a “laterally-extended bit line”.

The bit line 130 may include a conductive material. The bit line 130 may include a silicon-base material, a metal-base material, or a combination thereof. The bit line 130 may include polysilicon, metal, metal nitride, metal silicide, or a combination thereof.

The bit line 130 may include polysilicon, titanium nitride, tungsten (W), or a combination thereof. For example, the bit line BL may include polysilicon or titanium nitride (TiN) doped with N-type impurities.

The bit line 130 may include a stack TiN/W of titanium nitride (TiN) and tungsten (W). The bit line 130 may further include an ohmic contact layer such as metal silicide.

The vertical pattern 210 may have a shape extending in the third direction (Z direction), and one side of the vertical pattern 210 may be in contact with the bit line 130. The vertical pattern 210 may be located on the bit line 130. The vertical patterns 210 may be disposed to be spaced apart from each other and may have a distance in the first direction (X direction) and a distance in the second direction (Y direction) which are mutually set in advance.

The vertical pattern 210 may be repeatedly disposed on the bit line 130 in the shape of a matrix. The vertical pattern 210 may include a semiconductor region 211 and a gate insulating layer 212.

The semiconductor region 211 may be a region including a channel, a source, and a drain therein. The semiconductor region 211 may include doped polysilicon, undoped polysilicon, amorphous silicon, indium gallium zinc oxygen semiconductor (IGZO), indium zinc oxide (IZO), indium tin oxide (ITO), indium oxide (InO3), or the like.

The gate insulating layer 212 may include an insulating material such as silicon nitride or silicon oxide.

The word line 220 may be in contact with a side surface of the vertical pattern 210 and may have a shape extending in the second direction (Y direction).

The word line 220 may be in common contact with sidewalls of the plurality of vertical patterns 210 disposed in the second direction (Y direction).

The word line 220 may include a first sub-word line 221, a second sub-word line 222, and a third sub-word line 223.

The first sub-word line 221, the second sub-word line 222, and the third sub-word line 223 may be electrically separated from the semiconductor region 211 by the gate insulating layer 212.

The first sub-word line 221, the second sub-word line 222, and the third sub-word line 223 may include a conductive material such as metal, metal nitride, or polysilicon.

The first sub-word line 221 may be disposed adjacent to the bit line 130. The second sub-word line 222 may be disposed to be spaced apart from the first sub-word line 221 in the third direction (Z direction). The third sub-word line 223 may be disposed to be spaced apart from the second sub-word line 222 in the third direction (Z direction).

A thickness (or a width of a cross-sectional area) of the first sub-word line 221 may be thinner (or less) than a thickness of the second sub-word line 222. Also, a thickness (or a width of a cross-sectional area) of the third sub-word line 223 may be thinner (or less) than the thickness of the second sub-word line 222.

According to an embodiment, the thickness (or the width of the cross-sectional area) of the first sub-word line 221 may be the same as the thickness (or the width of the cross-sectional area) of the third sub-word line 223.08

Each memory cell included in the memory cell array may include a vertical channel transistor. The vertical channel transistor may include, for example, the vertical pattern 210 and the word line 220. Whether a channel is formed in the semiconductor region 211 included in the vertical pattern 210 and whether the bit line 130 and the capacitor contact 310 are electrically connected may be determined depending on a voltage provided to the word line 220.

In detail, if the memory cell is in the active state, the boosting voltage VPP may be provided to the first sub-word line 221, the second sub-word line 222, and the third sub-word line 223, and thus, the channel may be formed in the semiconductor region 211. In this instance, the bit line 130 and the capacitor contact 310 may be electrically connected.

In contrast, if the memory cell is in the standby state, the second voltage VBB2 may be provided to the first sub-word line 221 and the third sub-word line 223, and the first voltage VBB1 may be provided to the second sub-word line 222.

The second voltage VBB2 provided to the first sub-word line 221 and the third sub-word line 223 may be a voltage greater than the first voltage VBB1 provided to the second sub-word line 222.

If the voltage greater than the voltage provided to the second sub-word line 222 is provided to the first sub-word line 221 and the third sub-word line 223, a leakage current capable of being generated between the word line 220 and the vertical pattern 210 may be reduced.

The word line insulating pattern 230 may be provided between the word lines 220 adjacent to each other. The word line insulating pattern 230 may include an insulating material such as silicon oxide or silicon nitride.

The word lines 220 adjacent to each other may be electrically separated by the word line insulating pattern 230. Also, the word line insulating pattern 230 may be located between the first sub-word line 221, the second sub-word line 222, and the third sub-word line 223 and may electrically separate sub-word lines.

According to an embodiment, the word line insulating pattern 230 may be formed of a structure including a plurality of insulating layers.

The capacitor contact 310 may be disposed on the vertical pattern 210. The capacitor contact 310 may be disposed to overlap the vertical pattern 210. The capacitor contact 310 may be repeatedly disposed in the first direction (X direction) and the second direction (Y direction).

The capacitor contact 310 may include, for example, a conductive material. The contact insulating pattern 320 may be disposed between the capacitor contacts 310 adjacent to each other. The contact insulating pattern 320 may include an insulating material such as silicon oxide or silicon nitride.

The vertical pattern 210 and the capacitor lower electrode 410 may be connected via the capacitor contact 310. The capacitor lower electrode 410 may be in the shape of a pillar extending in the third direction (Z direction).

The capacitor lower electrode 410 may include a conductive material. The conductive material may include, for example, a doped semiconductor material, metal nitride, or a metal material. The capacitor lower electrodes 410 may be repeatedly disposed in the first direction (X direction) and the second direction (Y direction).

The capacitor insulating pattern 420 may be disposed on the contact insulating pattern 320. The capacitor insulating pattern 420 may be used as a stop layer of an etching process for forming a capacitor pattern.

The capacitor insulating pattern 420 may include, for example, an insulating material such as silicon oxide or silicon nitride. In detail, the capacitor insulating pattern 420 may include a material having etch selectivity suitable to be used as an etching stop layer.

In an embodiment, the capacitor lower electrode 410 may be formed by selectively etching a preset area in an insulating material layer and depositing a conductive material layer in the etched area. In this instance, the capacitor insulating pattern 420 may be used as an etch stop layer to selectively etch the preset area.

The capacitor dielectric layer 430 may be a layer including a high-k material whose dielectric constant is greater than that of silicon oxide. In an embodiment, the capacitor dielectric layer 430 may include at least one of hafnium oxide, zirconium oxide, aluminum oxide, lanthanum oxide, titanium oxide, tantalum oxide, niobium oxide, or strontium titanium oxide.

The upper electrode 440, which is a layer disposed on the capacitor dielectric layer 430, may include a conductive material. The conductive material may include, for example, a doped semiconductor material, metal nitride, or a metal material.

A capacitor may include the capacitor lower electrode 410, the capacitor dielectric layer 430, and the upper electrode 440 and may operate as a storage element of a semiconductor device.

A word line which a semiconductor device of the present disclosure includes may include a plurality of sub-word lines.

The semiconductor device of the present disclosure may provide different voltages to the sub-word lines, respectively, during a time period in which the word line is set to a standby state.

During the time period in which the word line is set to the standby state, the semiconductor device of the present disclosure may set a voltage, which is provided to a first sub-word line adjacent to a bit line and a third sub-word line adjacent to a storage element, to be greater than a voltage which is provided to a second sub-word line between the first sub-word line and the third sub-word line, and thus, a leakage current may be prevented.

Hereinabove, although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The present disclosure is not limited to the exemplary embodiments and the accompanying drawings, but may be variously modified and altered by those skilled in the art to which the present disclosure pertains without departing from the spirit and scope of the present disclosure claimed in the following claims.

What is claimed is:

1. A semiconductor device comprising:
a substrate;
a vertical pattern including a semiconductor region and extending in a direction perpendicular to one surface of the substrate; and
a word line disposed in contact with a side surface of the vertical pattern and extending in a direction parallel to the one surface of the substrate,
wherein the word line includes:
a first sub-word line disposed adjacent to the substrate;
a second sub-word line located above the first sub-word line; and
a third sub-word line located above the second sub-word line.

2. The semiconductor device of claim 1, further comprising:
a word line driving circuit connected to the word line,
wherein the word line driving circuit includes a first keeping transistor,
wherein the first keeping transistor includes:
a source connected to the second sub-word line;
a drain connected to the first sub-word line and the third sub-word line; and
a gate configured to receive a first voltage.

3. The semiconductor device of claim 2, wherein the word line driving circuit further includes a second keeping transistor, and
wherein the second keeping transistor includes:
a source configured to receive the first voltage;
a drain connected to the second sub-word line; and
a gate configured to receive an inverted word line driving signal.

4. The semiconductor device of claim 2, wherein the word line driving circuit further includes a first transistor, and
wherein the first transistor includes:
a source configured to receive a first word line driving signal;
a drain connected to the second sub-word line; and
a gate configured to receive a word line enable signal.

5. The semiconductor device of claim 2, wherein the word line driving circuit further includes a second transistor, and
wherein the second transistor includes:
a source configured to receive the first voltage;
a drain connected to the second sub-word line; and
a gate configured to receive a word line enable signal.

6. The semiconductor device of claim 2, wherein the word line driving circuit is configured to: provide the first voltage to the second sub-word line and provide a second voltage to the first sub-word line and the third sub-word line, during a time period in which the word line is set to a standby state.

7. The semiconductor device of claim 1, wherein a width of a cross-sectional area of the first sub-word line is less than a width of a cross-sectional area of the second sub-word line, and
wherein a width of a cross-sectional area of the third sub-word line is less than the width of the cross-sectional area of the second sub-word line.

8. The semiconductor device of claim 1, wherein a width of a cross-sectional area of the first sub-word line is the same as a width of a cross-sectional area of the third sub-word line.

9. The semiconductor device of claim 1, further comprising:
a bit line, extending in the direction parallel to the one surface of the substrate, disposed in contact with the semiconductor region.

10. The semiconductor device of claim 9, wherein the bit line extends in a direction perpendicular to the word line.

11. A semiconductor device comprising:
a bit line extending in a first direction;
a vertical pattern extending in a third direction perpendicular to the first direction, wherein one side of the vertical pattern is in contact with the bit line;
a storage element disposed in contact with an opposite side of the vertical pattern;
a first sub-word line disposed in contact with a side surface of the vertical pattern and extending in a second direction perpendicular to the third direction;
a second sub-word line disposed in contact with the side surface of the vertical pattern and spaced apart from the first sub-word line in the third direction;
a third sub-word line disposed in contact with the side surface of the vertical pattern and spaced apart from the second sub-word line in the third direction; and
a first keeping transistor connected to the first sub-word line, the second sub-word line, and the third sub-word line,
wherein the first keeping transistor includes:
a drain connected to the first sub-word line and the third sub-word line;
a source connected to the second sub-word line; and
a gate configured to receive a first voltage.

12. The semiconductor device of claim 11, wherein the first keeping transistor includes a PMOS transistor.

13. The semiconductor device of claim 11, further comprising:
a second keeping transistor,
wherein the second keeping transistor includes:
a source configured to receive the first voltage;
a drain connected to the second sub-word line; and
a gate configured to receive an inverted word line driving signal.

14. The semiconductor device of claim 12, wherein the second keeping transistor includes an NMOS transistor.

15. The semiconductor device of claim 11, further comprising:
a first transistor,
wherein the first transistor includes:
a source configured to receive a word line driving signal;
a drain connected to the second sub-word line; and
a gate configured to receive a word line enable signal.

16. The semiconductor device of claim 15, wherein the first transistor includes a PMOS transistor.

17. The semiconductor device of claim 11, further comprising:
a second transistor,
wherein the second transistor includes:
a source configured to receive the first voltage;
a drain connected to the second sub-word line; and
a gate configured to receive a word line enable signal.

18. The semiconductor device of claim 17, wherein the second transistor includes an NMOS transistor.

19. The semiconductor device of claim 11, wherein the first voltage is provided to the second sub-word line during a time period in which the first sub-word line, the second sub-word line, and the third sub-word line are set to a standby state, and
wherein a second voltage is provided to the first sub-word line and the third sub-word line.

20. The semiconductor device of claim 19, wherein the second voltage is greater than the first voltage.
